(19) United States
(12) Patent Application Publication
(10) Pub. No.: US 2025/0183131 A1
(43) Pub. Date: Jun. 5, 2025

(54) SEMICONDUCTOR DEVICE, ELECTRONIC DEVICE, AND METHOD OF MANUFACTURING ELECTRONIC DEVICE

(71) Applicant: Renesas Electronics Corporation, Tokyo (JP)

(72) Inventor: Toshiyuki HATA, Tokyo (JP)

(21) Appl. No.: 18/917,070

(22) Filed: Oct. 16, 2024

(30) Foreign Application Priority Data
Dec. 1, 2023 (JP) 2023-204081

(51) Int. Cl. H01L 23/495; H01L 21/48; H01L 23/00; H01L 23/31; H01L 23/367; H01L 23/40; H01L 23/538; H01L 25/00; H01L 25/10

(52) U.S. Cl. CPC H01L 23/49555; H01L 21/4853; H01L 23/3675; H01L 23/4006; H01L 23/538; H01L 25/105; H01L 25/50; H01L 23/3107; H01L 24/32; H01L 2224/32245

(57) ABSTRACT

Performance of a semiconductor device is improved. A semiconductor device includes a semiconductor chip, a sealing body having an upper surface and a lower surface, a plurality of leads, and a metal plate exposed from the sealing body at the upper surface of the sealing body. An outer lead portion of each of the plurality of leads includes a portion extending from the upper surface toward the lower surface in a thickness direction of the sealing body. The portion includes an end of the outer lead portion. When it is assumed that the lower surface is a reference surface in side view, in the thickness direction of the sealing body, a distance from the end of the outer lead portion to the reference surface is less than a distance from the upper surface to the reference surface.

### CROSS-REFERENCE TO RELATED APPLICATIONS

The disclosure of Japanese Patent Application No. 2023-204081 filed on Dec. 1, 2023, including the specification, drawings and abstract is incorporated herein by reference in its entirety.

### BACKGROUND

The present invention relates to a semiconductor device, an electronic device, and a method of manufacturing the electronic device.

There is disclosed technique listed below.
[Patent Document 1] Japanese Unexamined Patent Application Publication No. 2019-12767

There is an electronic device in which a lead is electrically connected with a board by inserting the lead exposed from a sealing body into a through-hole formed in the board (see, for example, Patent Document 1).

When a semiconductor device in which a lead is inserted into a through-hole formed in a mounting board is mounted on the mounting board, the layout of not only one surface (a mounting surface on which the semiconductor device is mounted) of the mounting board but also a surface opposite the mounting surface are limited by the through-hole. In the mounting board including a plurality of wiring layers between the mounting surface and its opposite surface, the wiring layout of each of the wiring layers is limited by the through-hole.

As a method for mounting the semiconductor device without forming the through-hole in the mounting board, a method of forming a terminal on a mounting surface of the mounting board and connecting the lead onto the terminal through solder is exemplified. A semiconductor device used for the mounting method is called a surface-mount semiconductor device. The surface-mount semiconductor device is configured so that an end of the lead is bent so that the end of the lead faces the terminal. This case causes an error in height of an upper surface of the semiconductor device arranged on the terminal, depending on lead shaping accuracy. If a terminal to be connected with other member is exposed at the upper surface of the semiconductor device, the accuracy in the height of the upper surface of the semiconductor device is preferably improved.

Other problems and novel characteristics will become apparent from the description of the present specification and the drawings.

A semiconductor device according to one embodiment includes: a semiconductor chip; a sealing body including: a first surface, and a second surface opposite the first surface and configured to seal the semiconductor chip; a plurality of leads electrically connected with the semiconductor chip; and a metal plate including a first exposed surface exposed from the sealing body at the first surface of the sealing body. Each of the plurality of leads includes: an inner lead portion sealed with the sealing body; and an outer lead portion exposed from the sealing body. The outer lead portion includes a first portion extending from the first surface toward the second surface in a thickness direction of the sealing body. The first portion includes an end of the outer lead portion. When it is assumed that the second surface is a first reference surface in side view, in the thickness direction of the sealing body, a distance from the end of the outer lead portion to the first reference surface is less than a distance from the first surface to the first reference surface.

An electronic device according to another embodiment includes: a mounting board including a mounting surface; a first semiconductor device mounted on the mounting surface of the mounting board; a second semiconductor device mounted on the mounting surface of the mounting board so as to be adjacent to the first semiconductor device; and a heat sink fixed onto each of the first semiconductor device and the second semiconductor device and straddling the first semiconductor device and the second semiconductor device. Each of the first semiconductor device and the second semiconductor device includes: a semiconductor chip; a sealing body including: a first surface facing the heat sink, and a second surface opposite the first surface and configured to seal the semiconductor chip; a plurality of leads electrically connected with the semiconductor chip; and a metal plate including a first exposed surface exposed from the sealing body at the first surface of the sealing body. Each of the plurality of leads includes: an inner lead portion sealed with the sealing body; and an outer lead portion exposed from the sealing body. The outer lead portion includes a first portion extending from the first surface toward the second surface in a thickness direction of the sealing body. When it is assumed that the second surface is a first reference surface in side view, in the thickness direction of the sealing body a distance from an end of the outer lead portion to the first reference surface is less than a distance from the first surface to the first reference surface. The second surface of each of the first semiconductor device and the second semiconductor device is in contact with the mounting surface of the mounting board.

A method of manufacturing an electronic device according to still another embodiment includes: a step (a) of preparing a mounting board including a mounting surface, a first insulating film provided on the mounting surface, a plurality of terminals exposed from the first insulating film at a plurality of opening portions formed in the first insulating film, and a first insulating layer on which the plurality of terminals is formed; a step (b) of mounting a first semiconductor device and a second semiconductor device on the mounting board such that the first semiconductor device and the second semiconductor device are adjacent to each other; and a step (c) of, after the step (b), fixing a heat sink onto each of the first semiconductor device and the second semiconductor device so as to straddle the first semiconductor device and the second semiconductor device. Each of the first semiconductor device and the second semiconductor device includes: a semiconductor chip; a sealing body including: a first surface facing the heat sink, and a second surface opposite the first surface and configured to seal the semiconductor chip; a plurality of leads electrically connected with the semiconductor chip; and a metal plate including a first exposed surface exposed from the sealing body at the first surface of the sealing body. Each of the plurality of leads includes: an inner lead portion sealed with the sealing body; and an outer lead portion exposed from the sealing body. The outer lead portion includes a first portion extending from the first surface toward the second surface in a thickness direction of the sealing body. When it is assumed that the second surface is a first reference surface in side view, in the thickness direction of the sealing body, a distance from an end of the outer lead portion to the first reference surface is less than a distance from the first surface to the first reference surface. In the step (b), the first semiconductor device and the second semiconductor device are arranged such that the second surface of each of the first semiconductor device and the second semiconductor device is in contact with the mounting surface of the mounting board.

### BRIEF DESCRIPTIONS OF THE DRAWINGS

FIG. 1 is a top view of a semiconductor device according to one embodiment.

FIG. 2 is a bottom view of the semiconductor device of FIG. 1.

FIG. 3 is a see-through plan view illustrating an inner structure of the semiconductor device from which a sealing body of FIG. 2 is removed.

FIG. 4 is a cross-sectional view taken along the line A-A of FIG. 3.

FIG. 5 is a side view of the semiconductor device of FIG. 1 viewed in a Y direction.

FIG. 6 is a side view of the semiconductor device of FIG. 1 viewed in an X direction.

FIG. 7 is an explanatory diagram schematically illustrating an exemplary circuit included in the semiconductor device of FIG. 1.

FIG. 8 is a cross-sectional view of a principal part illustrating an exemplary element structure of a field effect transistor of FIG. 7.

FIG. 9 is a top view of a semiconductor device as a modification example of FIG. 1.

FIG. 10 is a bottom view of the semiconductor device of FIG. 9.

FIG. 11 is a see-through plan view illustrating an inner structure of the semiconductor device from which a sealing body of FIG. 10 is removed.

FIG. 12 is a cross-sectional view taken along the line B-B of FIG. 11.

FIG. 13 is an explanatory diagram illustrating an exemplary circuit structure of an electronic device including the semiconductor device described with reference to FIGS. 1 to 12.

FIG. 14 is a top view of the electronic device of FIG. 13.

FIG. 15 is a cross-sectional view taken along the line C-C of FIG. 14.

FIG. 16 is an explanatory diagram illustrating exemplary steps of manufacturing the electronic device described with reference to FIGS. 13 to 15.

FIG. 17 is an explanatory diagram illustrating a modification example of the manufacturing steps of FIG. 16.

FIG. 18 is an enlarged cross-sectional view illustrating an electronic device as a modification example of FIG. 15.

FIG. 19 is an enlarged cross-sectional view illustrating an electronic device as a modification example of FIG. 18.

FIG. 20 is an explanatory diagram illustrating exemplary steps of manufacturing the electronic device of FIG. 18 or the electronic device of FIG. 19.

FIG. 21 is an enlarged cross-sectional view illustrating another modification example of FIG. 15.

FIG. 22 is an enlarged cross-sectional view illustrating one of a plurality of leads of FIG. 21 to be enlarged.

### SUMMARY

### (Explanation of Description Form, Basic Term and Usage in Present Application)

In the present application, the embodiments will be described in a plurality of sections or others as needed when required as a matter of convenience. However, these sections or others are not irrelevant to each other unless otherwise particularly stated. Regardless of before and after the description, one part of a simple example is a detailed part or a part or the entire of a modification example of the other. Also, in principle, the repetitive description of the same part is omitted. Further, each element in the embodiment is not indispensable unless otherwise particularly stated not to be so, logically limited to the number, and clearly not being so from the contexts.

Similarly, when a material, a composition or others is described as “X made of A” or others in the description of the embodiments or others, the one containing other components than A is not excluded unless otherwise stated not to be so and clearly not being so from the contexts. For example, the component means “X containing A as a main component” or others. For example, it is needless to say that a “silicon material” and others includes not only pure silicon but also SiGe (silicon germanium) alloy or other multicomponent alloy containing silicon as a main component, or a material containing other additives or others. Also, gold plating, a Cu layer, nickel plating, and others include not only pure material but also members containing gold, Cu, nickel, and others as a main component, respectively, unless otherwise specified not to be so or clearly stated so.

Further, even when a specific numerical value and numerical amount are mentioned, the specific numerical value and the numerical amount may be larger the specific numerical values or smaller than the specific numerical values unless otherwise specified not to be so, logically limited to the number, and clearly not being so from the contents.

Still further, in each drawing of the embodiment, the same or similar parts are denoted by the same or similar symbol or reference number, and the description thereof is not repeated in principle.

Also, in the attached drawings, hatching or others may be omitted even in a cross-sectional view in some cases such as a case of causing complication or a case of clearly distinguishing a portion from a space. In respect to this, a background outline may be omitted even in a closed hole in a plan view when being clear from the explanation or others. Further, hatching or a dot pattern may be added to a drawing in some cases in order to clearly show that the portion is not the space or clearly show a boundary between regions even if the drawing is not a cross-sectional view.

In the embodiments described below, as an example of the semiconductor device, a semiconductor device that is called a power device or a power semiconductor device embedded in a power controller circuit such as a power supply circuit will be exemplified and described. The semiconductor device described below is embedded in a power converter circuit to function as, for example, a switching element.

### <Semiconductor Device>

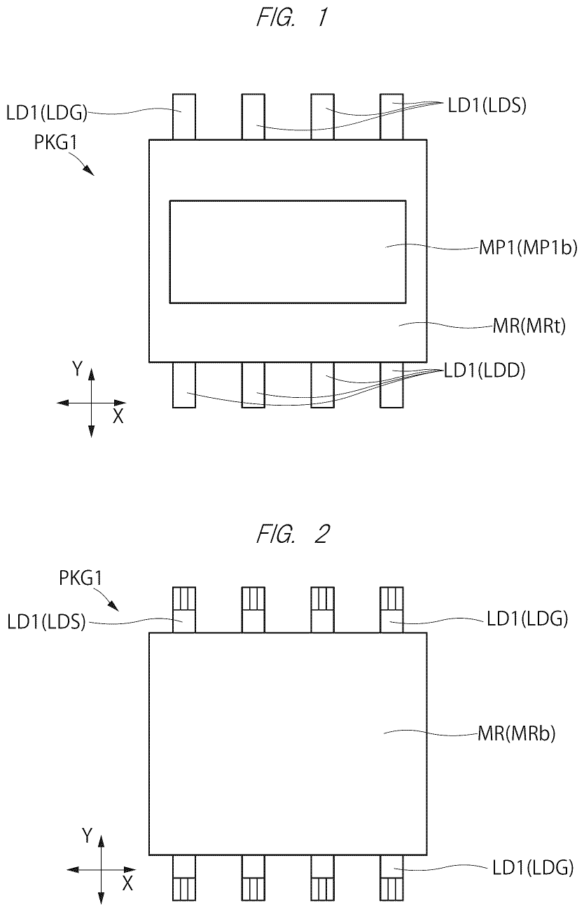

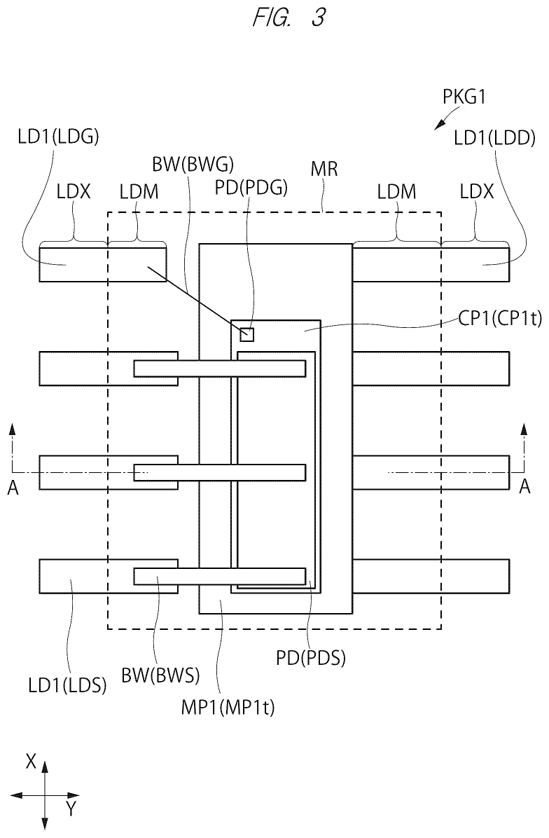

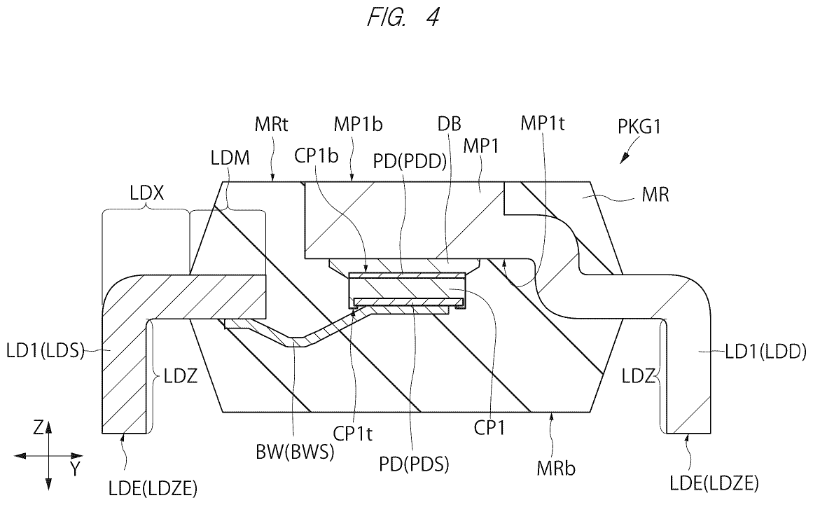

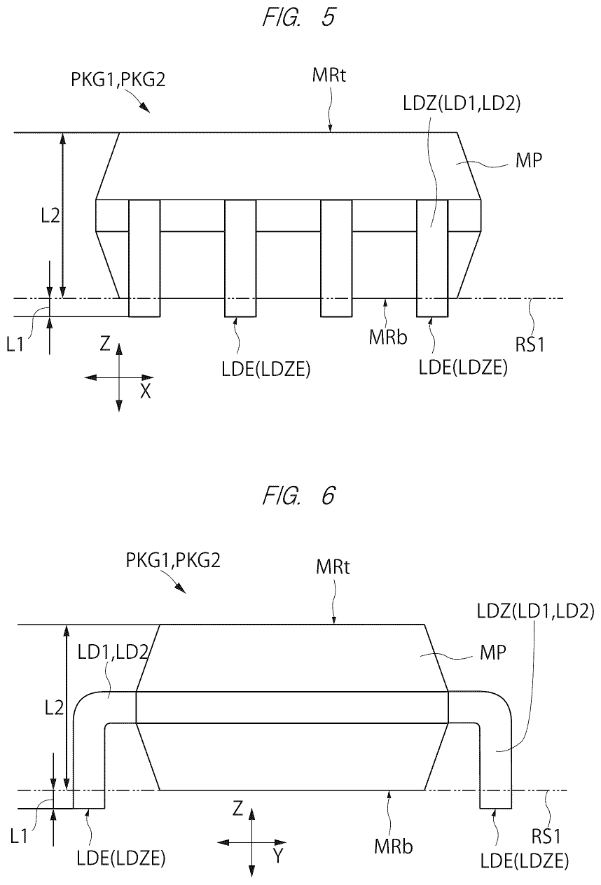

First, a package structure of a semiconductor device PKG1 of FIG. 1 will be described. FIG. 1 is a top view of the semiconductor device according to the present embodiment. FIG. 2 is a bottom view of the semiconductor device of FIG. 1. FIG. 3 is a see-through plan view illustrating an inner structure of the semiconductor device from which a sealing body of FIG. 2 is removed. FIG. 4 is a cross-sectional view taken along the line A-A of FIG. 3. FIG. 5 is a side view of the semiconductor device of FIG. 1 viewed in a Y direction. FIG. 6 is a side view of the semiconductor device of FIG. 1 viewed in an X direction.

FIGS. 1 to 6 illustrate any of X direction, Y direction, and Z direction. The Y direction is a direction crossing the X direction, and the X direction and the Y direction are orthogonal to each other in the following description. The Z direction is a direction being orthogonal to the X direction and the Y direction. In other words, the Z direction is a normal-line direction with respect to an X-Y plane including the X direction and the Y direction. In the following description, a term “thickness” means a length in the Z direction in principle. In the following description, a term “plan view” means viewing of the X-Y plane in principle. Also, a term “side view” means viewing of, for example, a plane including the Z direction, such as an “X-Z plane” and a “Y-Z plane”.

The semiconductor device PKG1 according to the present embodiment includes a semiconductor chip CP1 (see FIGS. 3 and 4), a sealing body MR configured to seal the semiconductor chip CP1, a plurality of leads LD1 electrically connected with the semiconductor chip CP1, and a metal plate MP1.

As illustrated in FIGS. 1 and 2, the sealing body MR has a quadrangular shape in plan view. In other words, the sealing body MR has four sides in plan view. The sealing body MR has an upper surface MRt (see FIG. 1) and a lower surface MRb (see FIG. 4) opposite the upper surface MRt. The sealing body MR is an insulator made of resin. The sealing body MR may contain pigments or inorganic insulating particles (such as silica) in addition to thermosetting resin.

In the present embodiment, the metal plate MP1 of FIG. 4 functions as a chip mounting section (die pad) on which the semiconductor chip CP1 is mounted. The metal plate MP1 has an exposed surface (surface, upper surface) MP1b and a chip mounting surface (surface, lower surface) MP1t opposite the exposed surface MP1b. The exposed surface MP1b is exposed from the sealing body MR at the upper surface MRt of the sealing body MR. The metal plate MP1 is made of a metallic material containing, for example, copper, copper alloy, or iron such as 42alloy.

As illustrated in FIGS. 3 and 4, the semiconductor chip CP1 is mounted on the chip mounting surface MP1t of the metal plate MP1 as the die pad. As illustrated in FIG. 4, the semiconductor chip CP1 has an upper surface (surface, front surface, main surface) CP1t and a lower surface (surface, back surface, main surface) CP1b opposite the upper surface CP1t. The semiconductor chip CP1 is mounted on the chip mounting surface MP1t through a die bonding material DB so that the lower surface CP1b faces the chip mounting surface MP1t of the metal plate MP1.

The die bonding material DB is, for example, solder or conductive resin. The conductive resin is resin in which a plurality of conductive particles are mixed into a resin component containing thermosetting resin such as epoxy resin. The conductive resin is referred to as conductive resin paste (particularly, silver paste when the conductive particles are silver particles) because of being in paste form before the thermosetting resin component contained in the conductive resin cures. As a modification example of the present embodiment, the semiconductor chip CP1 may not be electrically connected with the metal plate MP1. This case may adopt an insulating resin adhesive in which the die bonding material DB does not contain the conductive particles.

The semiconductor chip CP1 according to the present embodiment includes a power transistor made of a power metal-oxide-semiconductor field-effect transistor (MOSFET) or an insulated gate bipolar transistor (IGBT) as described later. The semiconductor chip CP1 including the power MOSFET will be exemplified and described below as an example. The term “power MOSFET” may be rephrased with the “IGBT” in the following description. In this case, terms “drain” and “source” are rephrased with “collector” and “emitter,” respectively.

As illustrated in FIGS. 3 and 4, the semiconductor chip CP1 includes a plurality of pads PD. As illustrated in FIG. 3, the semiconductor chip CP1 includes a gate electrode pad PDG and a source electrode pad PDS on the upper surface CP1t. Specifically, a plurality of opening portions are arranged in an insulating film (passivation film) including the upper surface CP1t of the semiconductor chip CP1. A gate electrode pad PDG and a source electrode pad PDS are exposed from the insulating film at the opening portions. An area of the source electrode pad PDS is larger than an area of the gate electrode pad PDG. The gate electrode pad PDG is an electrode pad connected with a gate electrode of the power MOSFET. The source electrode pad PDS is an electrode pad connected with a source of the power MOSFET.

As illustrated in FIG. 4, the semiconductor chip CP1 includes a drain electrode pad PDD formed on the lower surface CP1b. The drain electrode pad PDD is formed on, for example, the entire lower surface CP1b of the semiconductor chip CP1. The drain electrode pad PDD is an electrode pad connected with a drain of the power MOSFET.

In the present embodiment, the metal plate MP1 is electrically connected with the semiconductor chip CP1. Specifically, the metal plate MP1 is electrically connected with the drain electrode pad PDD of the semiconductor chip CP1 through the die bonding material DB as a conductive member. The metal plate MP1 is formed integrally with a lead LDD that is a drain lead among the plurality of leads LD1 of FIG. 3. The metal plate MP1 configures a drain current channel.

As illustrated in FIGS. 3 and 4, each of the plurality of leads LD1 includes an inner lead section (inner lead portion) LDM sealed with the sealing body MR and an outer lead section (outer lead portion) LDX exposed from the sealing body MR. As illustrated in FIG. 1, the plurality of leads LD1 are arranged on only two sides that are opposite each other, among the four sides of the sealing body MR in plan view. The outer lead section LDX (see FIG. 3) of each of the plurality of leads LD1 protrudes outward from the side surface of the sealing body MR.

Each of the plurality of leads LD1 is arranged on two sides among the four sides as described above. The semiconductor device in which the plurality of leads LD1 are arranged on two sides is referred to as small outline package (SOP) or dual in-line package (DIP). Note that the SOP is a name of a surface-mount semiconductor device with the leads shaped into gull-wing shape. To the contrary, the DIP is a name of a semiconductor device in which the plurality of leads linearly extend in the thickness direction of the sealing body. The DIP is mounted on a mounting board including through-holes. When the DIP is mounted on the mounting board, the plurality of leads are inserted into the plurality of through-holes, and the plurality of leads are fixed thereto by solder.

A gate lead LDG among the plurality of leads LD1 is electrically connected with the gate electrode pad PDG through a wire BW (specifically, a gate wire BWG). A plurality of source leads LDS among the plurality of leads LD1 are electrically connected with the source electrode pad PDS through a plurality of wires BW (specifically, source wires BWS). The lead LDD that is the drain lead among the plurality of leads LD1 is formed integrally with the metal plate MP1, and is electrically connected with the drain electrode pad PDD through the metal plate MP1. In the example of FIG. 3, the plurality of source leads LDS are apart from each other. However, as illustrated in FIG. 11 described later, the inner lead sections LDM of the adjacent leads LDS may be mutually coupled through a coupling section.

Note that the technique described below may be applied to the surface-mount semiconductor device such as the SOP. However, in the present embodiment, as illustrated in FIG. 4, the outer lead section LDX includes a section (portion) LDZ extending from the upper surface MRt toward the lower surface MRb in the thickness direction of the sealing body MR. The section LDZ includes an end LDE of the outer lead section LDX. In other words, the end LDE of the outer lead section LDX coincides with an end LDZE of the section LDZ. Thus, the semiconductor device PKG1 according to the present embodiment is classified to a semiconductor package closer to the DIP than the SOP.

However, the semiconductor device PKG1 according to the present embodiment is not so designed that each of the plurality of leads LD1 is inserted into the through-hole in the mounting board. This is different from a typical DIP in this point. As illustrated in FIGS. 5 and 6, in case the semiconductor device PKG1, when it is assumed that the lower surface MRb of the sealing body MR is the reference surface RS1 in side view, in the thickness direction of the sealing body MR, the distance L1 between the end LDE and the reference surface RS1 is less than the distance L2 between the upper surface MRt and the reference surface RS1.

### <Exemplary Circuit Structure>

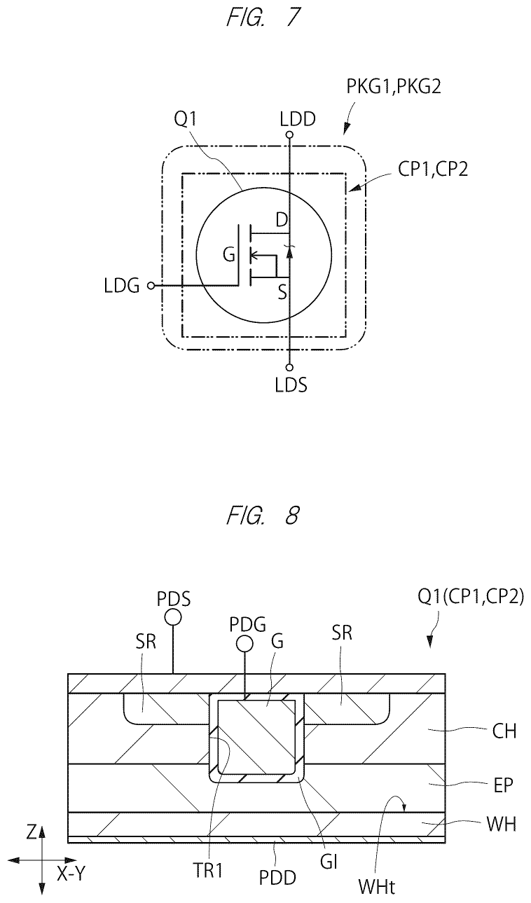

Next, an exemplary structure of a circuit included in the semiconductor device PKG1 of FIG. 3 and an exemplary element structure of the transistor will be described. FIG. 7 is an explanatory diagram schematically illustrating an exemplary circuit included in the semiconductor device of FIG. 1. FIG. 8 is a cross-sectional view of a principal part illustrating an exemplary element structure of a field effect transistor of FIG. 7.

A power control semiconductor device called power semiconductor device may include a semiconductor element such as diode, thyristor, or transistor. The transistor is used in various fields, and a transistor operating as the switching element and embedded in the power controller circuit through which large current of, for example, 1 A or more flows as in the present embodiment is called power transistor. The semiconductor device PKG1 according to the present embodiment includes the semiconductor chip CP1 including a transistor Q1 that is the power transistor as illustrated in FIG. 7. In the example of FIGS. 7 and 8, the transistor Q1 included in the semiconductor chip CP1 is a field effect transistor, more specifically a MOSFET. The transistor in the power semiconductor device is utilized as, for example, the switching element. The MOSFET used in the power semiconductor device is called power MOSFET.

The term “MOSFET” is described as a term widely representing a field effect transistor in which a gate electrode made of a conductive material is arranged on a gate insulating film. Thus, even the term MOSFET does not exclude the gate insulating film other than the oxide film. The term MOSFET does not exclude the gate electrode material such as polysilicon other than the metal.

The transistor Q1 of FIG. 7 is made of, for example, an n-channel field effect transistor as illustrated in FIG. 8. FIG. 8 is a cross-sectional view of a principal part illustrating an exemplary element structure of the field effect transistor of FIG. 7.

In the example of FIG. 8, for example, an n-type epitaxial layer EP is formed on a main surface WHt of a semiconductor substrate WH made of n-type monocrystal silicon. The semiconductor substrate WH and the epitaxial layer EP configure a drain region (corresponding to the drain D of FIG. 7) of the MOSFET. The drain region is electrically connected with the drain electrode pad PDD formed on the back surface of the semiconductor chip CP1.

A channel forming region CH that is a p⁺-type semiconductor region is formed on the epitaxial layer EP, and a source region (corresponding to the source S of FIG. 7) SR that is an n⁺-type semiconductor region is formed on the channel forming region CH. The source region SR is electrically connected with the source electrode pad PDS of the semiconductor chip CP1 through a drawn-out wiring. A trench (opening portion, groove) TR1, which penetrates through the channel forming region CH from an upper surface of the source region SR and reaches inside the epitaxial layer EP, is formed in a semiconductor region stacked on the semiconductor substrate WH.

A gate insulating film G1 is arranged on the inner wall of the trench TR1. The gate electrode G stacked to fill the trench TR1 is arranged on the gate insulating film G1. The gate G is electrically connected with the gate electrode pad PDG of the semiconductor chip CP1 through a drawn-out wiring.

In the transistor Q1, the drain region and the source region SR are arranged across the channel forming region CH in the thickness direction, and thus channels are formed in the thickness direction (this will be called vertical-channel structure). In this case, the element-occupying area in plan view can be made smaller than that of a field effect transistor in which channels are formed along the main surface WHt. Thus, the plane size of the semiconductor chip CP1 can be reduced.

In the vertical-channel structure, a channel width per unit area in plan view can be increased, and therefore, an ON resistance can be reduced. FIG. 8 is a diagram illustrating an element structure of a field effect transistor in which a plurality of (a large number of) transistors Q1 having, for example, the element structure of FIG. 8 are connected in parallel in the semiconductor chip CP1 of FIG. 7. Therefore, the power MOSFET in which the large current exceeding, for example, 1 A flows can be configured.

When the MOSFET is configured by the parallel connection of the plurality of transistors Q1 having the vertical-channel structure as described above, electric properties (mainly withstand voltage property, ON resistance property, and capacity property) of the MOSFET varies depending on the plane size of the semiconductor chip CP1. For example, the larger the plane area of the semiconductor chip CP1 is, the larger the number of cells (that is the number of elements) of the transistors Q1 connected in parallel is, and therefore, the ON resistance decreases while the capacity increases.

In FIGS. 7 and 8, the MOSFET is exemplified as the power transistor included in the power semiconductor device. However, various modification examples are applicable. For example, instead of the MOSFET, an insulated gate bipolar transistor (IGBT) may be included.

In the example of FIG. 8, the transistor having the vertical-channel structure has been exemplified and described. However, a transistor having a horizontal-channel structure may be instead used. In this case, the drain electrode pad PDD is arranged on the upper surface CPt1 of the semiconductor chip CP1 (see FIG. 3). Thus, the drain lead LDD of FIG. 3 is electrically connected with the drain electrode pad PDD (see FIG. 8) connected with the drain of the transistor having the horizontal-channel structure through a wire (drain wire) not illustrated.

### <Modification Example of Semiconductor Device>

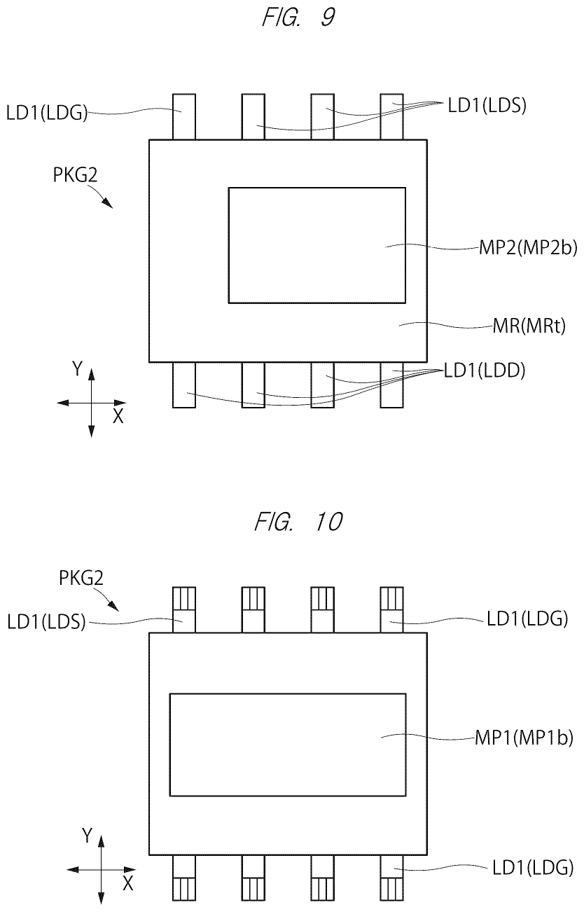

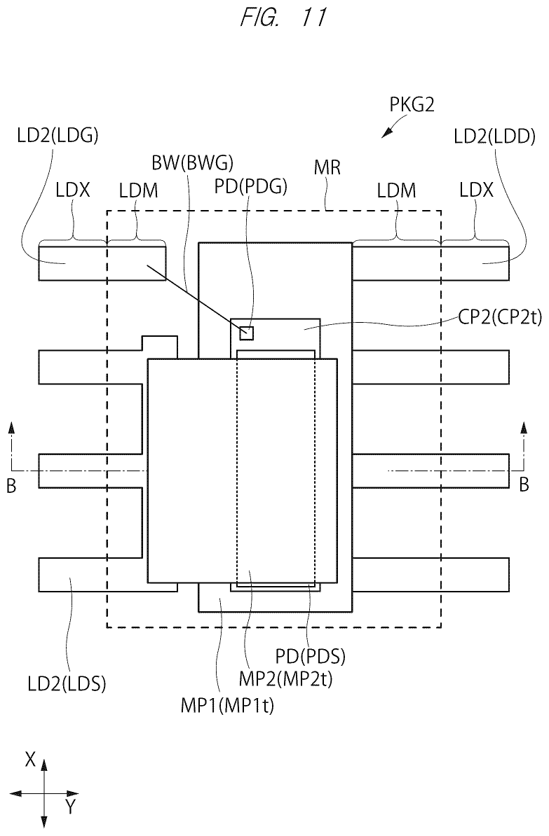

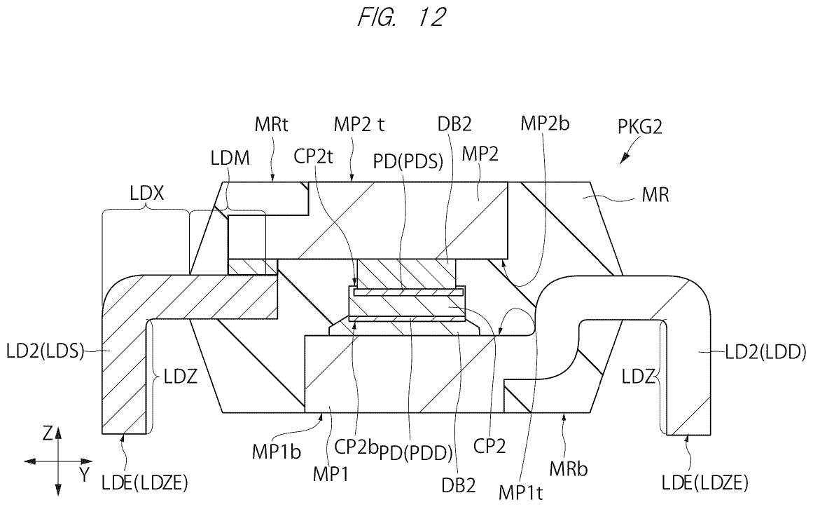

Next, a package structure of a modification example of the semiconductor device PKG1 explained with reference to FIGS. 1 to 8 will be described. FIG. 9 is a top view of a semiconductor device as a modification example of FIG. 1. FIG. 10 is a bottom view of the semiconductor device of FIG. 9. FIG. 11 is a see-through plan view illustrating an inner structure of the semiconductor device from which a sealing body of FIG. 10 is removed. FIG. 12 is a cross-sectional view taken along the line B-B of FIG. 11. Note that a side surface of a semiconductor device PKG2 of FIGS. 9 to 12 is the same as that of FIGS. 5 and 6. Also, a transistor included in a semiconductor chip CP2 of the semiconductor device PKG2 of FIGS. 11 and 12 is the same as the power transistor (MOSFET or IGBT) described with reference to FIGS. 7 and 8. Thus, in the following description, differences between the semiconductor device PKG1 and the semiconductor device PKG2 will be mainly described, and the description for the common parts therebetween will be omitted.

The semiconductor device PKG2 according to the present modification example includes the semiconductor chip CP2 (see FIGS. 11 and 12), the sealing body MR configured to seal the semiconductor chip CP2, a plurality of leads LD2 electrically connected with the semiconductor chip CP2, the metal plate MP1, and a metal plate MP2.

The metal plate MP1 of FIG. 12 functions as a chip mounting section (die pad) on which the semiconductor chip CP2 is mounted. An exposed surface MP1b of the metal plate MP1 is exposed from the sealing body MR at the lower surface MRb of the sealing body MR.

As illustrated in FIGS. 11 and 12, the semiconductor chip CP2 is mounted on the chip mounting surface MP1t of the metal plate MP1 as the die pad. As illustrated in FIG. 12, the semiconductor chip CP2 has an upper surface (surface, front surface, main surface) CP2t and a lower surface (surface, back surface, main surface) CP2b opposite the upper surface CP2t. The semiconductor chip CP2 is mounted on the chip mounting surface MP1t through the die bonding material DB so that the lower surface CP2b faces the chip mounting surface MP1t of the metal plate MP1. The semiconductor chip CP2 includes a power transistor made of a power MOSFET as similar to the semiconductor chip CP1 of FIGS. 3 and 4.

As illustrated in FIGS. 11 and 12, the semiconductor chip CP2 includes a plurality of pads PD. As illustrated in FIG. 11, the semiconductor chip CP2 includes a gate electrode pad PDG and a source electrode pad PDS on the upper surface CP2t. Specifically, a plurality of opening portions are arranged in an insulating film (passivation film) including the upper surface CP2t of the semiconductor chip CP2. Each of the gate electrode pad PDG and the source electrode pad PDS is exposed from the insulating film at the opening portion. An area of the source electrode pad PDS is larger than an area of the gate electrode pad PDG. The gate electrode pad PDG is an electrode pad connected with a gate electrode of the power MOSFET. The source electrode pad PDS is an electrode pad connected with a source of the power MOSFET.

As illustrated in FIG. 12, the semiconductor chip CP2 includes a drain electrode pad PDD formed on the lower surface CP2b. The drain electrode pad PDD is formed on, for example, the entire lower surface CP2b of the semiconductor chip CP2. The drain electrode pad PDD is an electrode pad connected with a drain of the power MOSFET.

The metal plate (clip) MP2 of FIG. 12 functions as a conductive member configured to electrically connect the source electrode pad PDS of the semiconductor chip CP2 and a source lead LDS among the plurality of leads LD2. The metal plate MP2 is electrically connected with the source electrode pad PDS of the semiconductor chip CP2 through a die bonding material DB2. A plate-shaped member configured to electrically connect the semiconductor chip and the lead is called a clip. In the present modification example, since the wire BWS of FIG. 4 is replaced with the metal plate MP2 of FIG. 11, a cross-sectional area of a path electrically connecting the source lead LDS and the source electrode pad PDS is larger than that of the example of FIG. 4. Thus, resistance of the path configured to supply the current flowing in the source electrode pad PDS can be reduced.

The metal plate MP2 has an exposed surface (surface, upper surface) MP2t and a chip opposing (facing) surface (surface, lower surface) MP2b opposite the exposed surface MP2t and facing the semiconductor chip CP2. The exposed surface MP2t is exposed from the sealing body MR at the upper surface MRt of the sealing body MR. The metal plate MP2 is made of a metallic material containing, for example, copper, copper alloy, or iron such as 42alloy.

A gate lead LDG among the plurality of leads is electrically connected with the gate electrode pad PDG through the wire BW (specifically, the gate wire BWG). A source lead LDS among the plurality of leads is electrically connected with the source electrode pad PDS through the metal plate MP2. A drain lead LDD among the plurality of leads is formed integrally with the metal plate MP1, and is electrically connected with the drain electrode pad PDD through the metal plate MP1.

As illustrated in FIGS. 5 and 6, as similar to the semiconductor device PKG1 described above, in the semiconductor device PKG2, if it is assumed that the lower surface MRb of the sealing body MR is a reference surface RS1 in side view, a distance L1 from an end LDE of the outer lead sections LDX to the reference surface RS1 is less than a distance L2 from the upper surface MRt of the sealing body MR to the reference surface RS1 in the thickness direction of the sealing body MR.

In the semiconductor device PKG1 illustrated in FIGS. 1 to 4 and the semiconductor device PKG2 illustrated in FIGS. 9 to 12, the metal plates (the metal plate MP1 of FIG. 1 and the metal plate MP2 of FIG. 9) are exposed at the upper surface MRt of the sealing body MR. When a part of the metal plate is exposed from the sealing body MR as described above, by thermal connection of a heat sink to the exposed portion of the metal plate, heat dissipation efficiency can be improved.

The metal plates connected with the heat sink may include not only the metal plate MP1 functioning as the die pad illustrated in FIG. 4 but also the metal plate MP2 functioning as the clip illustrated in FIG. 12.

### <Electronic Device>

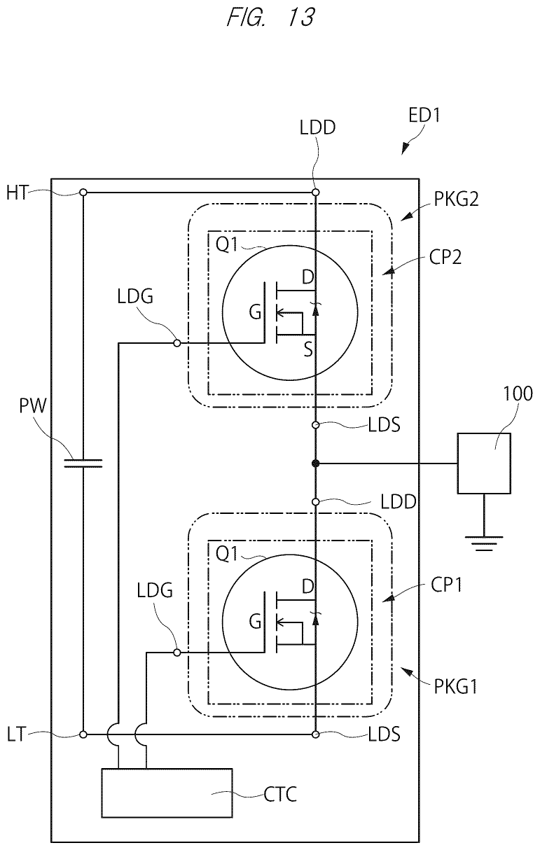

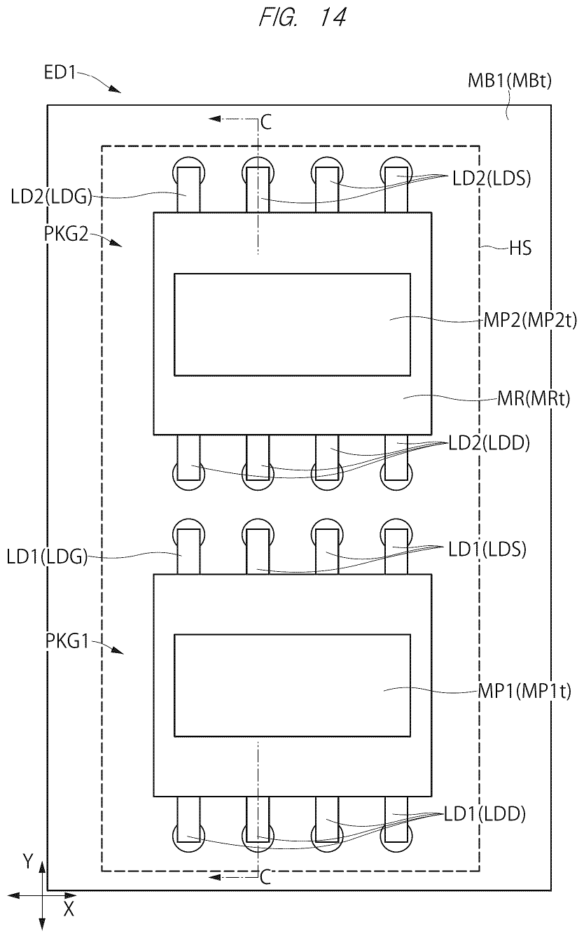

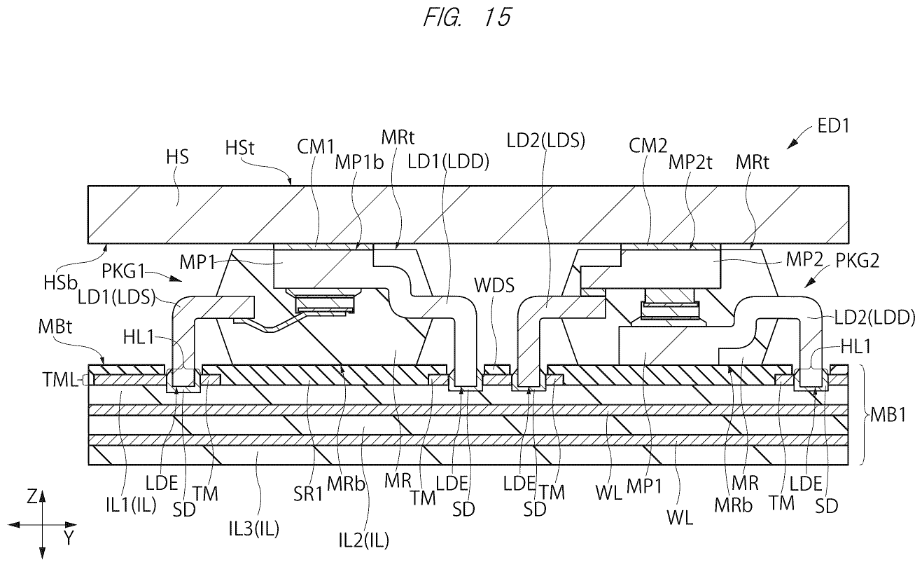

Next, an exemplary electronic device including the semiconductor device described with reference to FIGS. 1 to 12 will be described. FIG. 13 is an explanatory diagram illustrating an exemplary circuit structure of the electronic device including the semiconductor device described with reference to FIGS. 1 to 12.

An electronic device ED1 of FIG. 13 includes the semiconductor device PKG1 and the semiconductor device PKG2. As described above, each of the semiconductor chip CP1 in the semiconductor device PKG1 and the semiconductor chip CP2 in the semiconductor device PKG2 includes the power transistor made of the power MOSFET or the IGBT.

The lead LDD connected with the drain D of the semiconductor device PKG2 is connected with a terminal (high-side terminal) HT connected with a power supply PW. The lead LDS connected with the source S of the semiconductor device PKG1 is connected with a terminal (low-side terminal) LT connected with the power supply PW. To the terminal HT, a higher potential than that of the terminal LT is supplied.

The lead LDS of the semiconductor device PKG2 and the lead LDD of the semiconductor device PKG1 are electrically connected with each other, and are connected with a load 100. The lead LDG connected with the gate G of the semiconductor device PKG1 and the lead LDG connected with the gate G of the semiconductor device PKG2 are connected with a control circuit CTC.

In the example of FIG. 13, the electronic device ED1 includes an inverter circuit including the semiconductor device PKG1 and the semiconductor device PKG2. In the inverter circuit of FIG. 13, the semiconductor device PKG2 is used as a high-side switching element while the semiconductor device PKG1 is used as a low-side switching element.

Note that FIG. 13 illustrates a single-phase inverter circuit. However, in a case in which the number of sets of the semiconductor device PKG1 and the semiconductor device PKG2 illustrated in FIG. 13 is three, these semiconductor devices can be used as a three-phase inverter circuit.

FIG. 14 is a top view of the electronic device of FIG. 13. FIG. 15 is a cross-sectional view taken along the line C-C of FIG. 14. A heat sink HS of FIG. 14 covers the semiconductor device PKG1 and the semiconductor device PKG2. In FIG. 14, in order to clearly demonstrate a positional relationship among the heat sink HS and the semiconductor devices PKG1, PKG2, the heat sink HS is illustrated with a dotted line in the see-through plan view in which the heat sink is transparently viewed. In FIG. 14, a conductive member CM1 and a conductive member CM2 illustrated in FIG. 15 are not illustrated.

As illustrated in FIGS. 14 and 15, the electronic device ED1 includes a mounting board MB1, the semiconductor device PKG1, the semiconductor device PKG2, and the heat sink HS.

The mounting board MB1 has a mounting surface MBt. As illustrated in FIG. 15, the mounting board MB1 includes an insulating film SR1 provided on the mounting surface MBt, a plurality of terminals TM exposed from the insulating film SR1 at a plurality of opening portions formed in the insulating film SR1, and an insulating layer IL1 on which the terminals TM are formed. The insulating film SR1 is formed on the insulating layer IL1. The insulating layer IL1 is arranged in the uppermost layer (a layer nearest to a terminal-arranged layer TML in which the plurality of terminals TM are arranged) among a plurality of insulating layers IL (the insulating layer IL1, an insulating layer IL2, and an insulating layer IL3) in the mounting board MB1. The insulating layer IL1 is in contact with the plurality of terminals TM. The plurality of terminals TM and the plurality of leads (the leads LD1 and the leads LD2) are electrically connected with each other through solder (conductive member) SD.

The heat sink (metallic member) HS is a member configured to dissipate the heat generated in the semiconductor device PKG1 and the semiconductor device PKG2 to the atmosphere. The heat sink HS is made of, for example, a metal such as aluminum. The heat sink HS has a lower surface HSb facing the semiconductor device PKG1 and the semiconductor device PKG2 and an upper surface HSt opposite the lower surface HSb. FIG. 15 illustrates the heat sink HS made of a simple plate-shaped member as an example. A shape of the heat sink HS includes various modification examples. For example, a plurality of fins (protrusions) may be provided on the upper surface HSt. When a plurality of fins are provided on the upper surface HSt of the heat sink HS, the surface area of the heat sink HS can be made larger than that of the simple plate-shaped member, and thus, the heat dissipation efficiency can be improved.

The detailed structures of the semiconductor device PKG1 and the semiconductor device PKG2 of FIG. 15 have been as described above with reference to FIGS. 1 to 12, and thus, will not be repeatedly described.

As illustrated in FIG. 14, the semiconductor device PKG1 and the semiconductor device PKG2 are mounted on the mounting surface MBt of the mounting board MB1 so as to be adjacent to each other in plan view. As illustrated in FIG. 15, the heat sink HS is fixed to each of the semiconductor device PKG1 and the semiconductor device PKG2. The heat sink HS straddles the semiconductor device PKG1 and the semiconductor device PKG2.

In the example of FIG. 15, the exposed surface MP1b of the metal plate MP1 of the semiconductor device PKG1 is fixed to the heat sink HS through the conductive member CM1. The exposed surface MP2t of the metal plate MP2 of the semiconductor device PKG2 is fixed to the heat sink HS through the conductive member CM2. Each of the conductive member CM1 and the conductive member CM2 is made of, for example, solder or conductive resin. As described above, conductive resin is resin in which a plurality of conductive particles are mixed into a resin component containing thermosetting resin such as epoxy resin.

In the structure in which the semiconductor device PKG1 and the semiconductor device PKG2 are arranged so as to be adjacent to each other while one heat sink HS is fixed to both the semiconductor device PKG1 and the semiconductor device PKG2 as described in the present embodiment, heights of the upper surfaces MRt of the sealing body MR (in other words, a height of the exposed surface MP1b of the metal plate MP1 of the semiconductor device PKG1 and a height of the exposed surface MP2t of the metal plate MP2 of the semiconductor device PKG2) need to be equal to each other.

For example, when there is a large difference in height between the position of the upper surface MRt of the sealing body MR in the semiconductor device PKG1 and the position of the upper surface MRt of the sealing body MR in the semiconductor device PKG2, if the heat sink HS tilts, either the semiconductor device PKG1 or the semiconductor device PKG2 may not be fixed to the heat sink HS. In this case, the heat dissipation property of the semiconductor device not fixed to the heat sink HS is largely reduced.

In the electronic device on which the surface-mount semiconductor device is mounted, there are the following two factors for the large difference in height between the position of the upper surface MRt of the sealing body MR in the semiconductor device PKG1 and the position of the upper surface MRt of the sealing body MR in the semiconductor device PKG2.

First, if the end of the lead is bent, individual variability in the position of the upper surface MRt of the sealing body MR may be caused by tolerance of the bending of the lead. Second, individual variability in the position of the upper surface MRt of the sealing body MR may be caused by shaping tolerance in a step of shaping the sealing body MR under use of a mold. In a semiconductor device in which the sealing body MR is supported by the lead on the mounting board, the position of the upper surface MRt of the sealing body MR is varied by both factors that are the tolerance of the bending of the lead and the shaping tolerance in the step of shaping the sealing body MR.

In the present embodiment, in each of the semiconductor device PKG1 and the semiconductor device PKG2 as described with reference to FIGS. 5 and 6, if it is assumed that the lower surface MRb of the sealing body MR is the reference surface RS1 in side view, the distance L1 from the end LDE of the outer lead section LDX to the reference surface RS1 is less than the distance L2 from the upper surface MRt of the sealing body MR to the reference surface RS1 in the thickness direction of the sealing body MR. The lower surface MRb of each of the semiconductor device PKG1 and the semiconductor device PKG2 is in contact with the mounting surface MBt of the mounting board MB1.

In other words, the length of the lead LD1 (or the lead LD2) in the thickness direction of the sealing body MR is so small that the sealing body MR is in contact with the mounting surface MBt of the mounting board MB1. When the length of the lead LD1 (or the lead LD2) in the thickness direction of the sealing body MR is so small that the sealing body MR is in contact with the mounting surface MBt of the mounting board MB1, the factor that is the tolerance of the bending of the lead among the two factors can be eliminated.

As illustrated in FIG. 15, the semiconductor device PKG1 and the semiconductor device PKG2 are mounted on the mounting board MB1 so that the entire lower surfaces MRb is in contact with the insulating film SR1 including the mounting surface MBt of the mounting board MB1. In this case, although the individual variability in the position of the upper surface MRt of the sealing body MR is caused within a range of the tolerance in the step of shaping the sealing bodies MR, the factor due to the tolerance of the bending of the lead can be eliminated. Thus, although the semiconductor device PKG1 and the semiconductor device PKG2 are the surface-mount semiconductor devices, the difference in height can be decreased between the position of the upper surface MRt of the sealing body MR in the semiconductor device PKG1 and the position of the upper surface MRt of the sealing body MR in the semiconductor device PKG2.

In the example of FIGS. 14 and 15, the plurality of terminals TM are formed around a plurality of holes HL1 formed in the insulating layer IL1, respectively. Each of the plurality of holes HL1 is formed to penetrate through the terminal TM. The ends LDE of the outer lead sections LDX of the plurality of leads LD1 and the plurality of leads LD2 are inserted into the plurality of holes HL1, respectively. The solder SD is arranged in the plurality of holes HL1. Each of the plurality of leads LD1 and the plurality of leads LD2 is electrically connected with the terminal TM through the solder SD arranged in the hole HL1.

Although not illustrated, the holes HL1 illustrated in FIGS. 14 and 15 may not be formed in a modification example. In this case, each of the lead LD1 and the lead LD2 is electrically connected with the terminal TM through the solder SD applied on the terminal TM. In the structure in this modification example, the end LDE of each of the lead LD1 and the lead LD2 needs to be positioned higher than the lower surface MRb of the sealing body MR in order to bring the lower surface MRb of the sealing body MR into contact with the mounting surface MBt of the mounting board MB1.

If the ends LDE of the lead LD1 and the lead LD2 are positioned much higher than the lower surface MRb of the sealing body MR, there is a possibility of no contact of the lead LD1 and the lead LD2 with the solder SD. Thus, positioning accuracy of the ends LDE of the lead LD1 and the lead LD2 needs to be improved.

To the contrary, in the present embodiment, the lead LD1 and the lead LD2 have only to be bonded to the solder SD arranged in the hole HL1, and thus, a depth of the hole HL1 is adjusted to increase a margin for the positioning accuracy of the ends LDE of the lead LD1 and the lead LD2. The hole HL1 is so deep that the bottom surface of the hole HL1 is not in contact with the ends LDE of the lead LD1 and the lead LD2. Thus, as illustrated in FIG. 15, the semiconductor device PKG1 and the semiconductor device PKG2 can be mounted so that the entire lower surface MRb of the sealing body MR is in contact with the mounting surface MBt of the mounting board MB1.

As described with reference to FIG. 4, the sections LDZ of the plurality of leads LD1 of the semiconductor device PKG1 include the ends LDE of the outer lead sections LDX. In other words, the end LDE of the outer lead section LDX coincide with the end LDZE of the section LDZ. As illustrated in FIG. 12, the plurality of leads LD2 of the semiconductor device PKG2 are similar to the plurality of leads LD1 of FIG. 4. In this case, the contact area between the lead LD1 (or the lead LD2) and the solder SD of FIG. 15 is smaller than that of the typical surface-mount semiconductor device in which the end of the outer lead section LDX is bent.

As illustrated in FIG. 15, when the lead LD1 and the lead LD2 are inserted into the holes HL1, the bonding area between the leads LD1, LD2 and the solder SD increases. Consequently, the bonding strength between the leads LD1, LD2 and the solder SD can be improved.

Incidentally, the hole HL1 is preferably shallow in order to improve the degree of freedom of the wiring layout of the mounting board MB1. For example, in the example of FIG. 15, the mounting board MB1 includes a terminal-arranged layer TML in which the plurality of terminals TM are arranged, and a wiring layer WL that is lower than the terminal-arranged layer TML. The wiring layer WL is formed farther from the mounting surface MBt than the terminal-arranged layer TML. FIG. 15 illustrates two wiring layers WL. However, the number of wiring layers WL is not limited to two, and may be one, three or more.

If the hole HL1 is deeper than that in the example of FIG. 15 to reach, for example, the wiring layer WL, the wiring layer WL cannot be provided around the hole HL1 in order to avoid short circuit between the wiring layer WL and the terminal TM.

Thus, the following structure is preferable in order to improve the degree of freedom of the wiring layout of the wiring layer WL. That is, preferably, the plurality of holes HL1 penetrate through the terminals TM but do not penetrate through the insulating layer IL1.

As illustrated in FIGS. 14 and 15, the terminal TM connected with the drain lead LDD of the semiconductor device PKG1 and the terminal TM connected with the source lead LDS of the semiconductor device PKG2 are electrically connected with each other through a wiring WDS.

Therefore, the metal plate MP1 and the metal plate MP2 do not necessarily need to be electrically connected with the heat sink HS. However, in the following points, the metal plate MP1 of the semiconductor device PKG1 and the metal plate MP2 of the semiconductor device PKG2 are preferably electrically connected through the heat sink HS as described in the present embodiment.

For example, a conductive material generally has high heat conductivity. For example, the above-described solder and conductive resin (such as resin using silver particles as conductive particles) have high heat conductivity. Thus, when the heat sink HS is fixed to the semiconductor device PKG1 through the conductive member CM1, the heat conductivity of a heat dissipation path from the semiconductor device PKG1 to the heat sink HS can be improved. When the heat sink HS is fixed to the semiconductor device PKG2 through the conductive member CM2, the heat conductivity of a heat dissipation path from the semiconductor device PKG2 to the heat sink HS can be improved.

For example, when the metal plate MP1 of the semiconductor device PKG1 and the metal plate MP2 of the semiconductor device PKG2 are electrically connected through the heat sink HS, the heat sink HS can be used as a conductive path connected with the load 100 of FIG. 13.

Incidentally, as the solder SD of FIG. 15, various conductive members can be applied if the conductive member can ensure reliability in electric connection between the lead LD1 (or the lead LD2) and the terminal TM. For example, conductive resin may be used instead of the solder SD. However, when the solder SD is embedded in the hole HL1 as similar to the electronic device ED1, the solder SD is particularly applicable because air bubbles are less likely to be caused in the hole HL1.

As described above, each of the conductive member CM1 and the conductive member CM2 is made of solder or conductive resin. Although described in detail later, when each of the conductive member CM1 and the conductive member CM2 is made of solder, a reflow processing is performed on the conductive member CM1 and the conductive member CM2 together with the solder SD in the steps of manufacturing the electronic device ED1. The reflow processing is a processing of curing the solder by melting the solder in a heating processing and then cooling it.

To the contrary, when each of the conductive member CM1 and the conductive member CM2 is made of conductive resin, a curing and baking processing is performed on the conductive member CM1 and the conductive member CM2 after the reflow processing is performed on the solder SD in the steps of manufacturing the electronic device ED1. The curing and baking processing is a processing of curing the conductive resin by heating the thermosetting resin contained in the conductive resin to its curing temperature or higher.

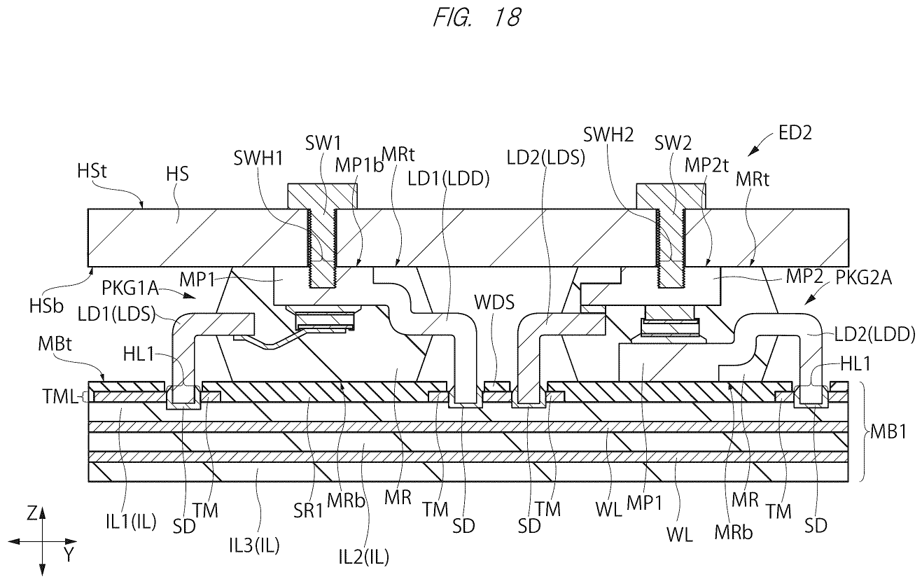

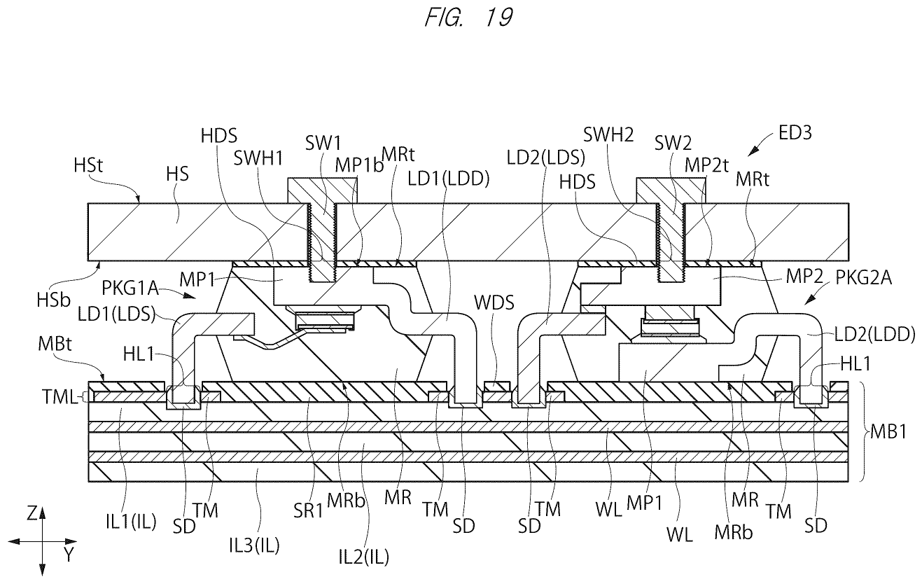

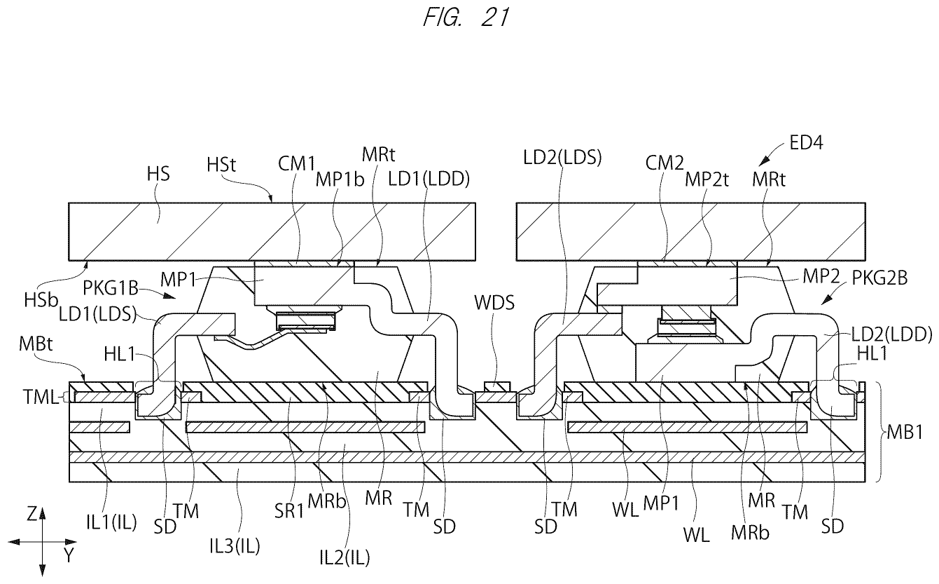

Note that the electronic device ED1 described in FIGS. 13 to 15 include various modification examples including an electronic device ED2 (see FIG. 18), an electronic device ED3 (see FIG. 19), and an electronic device ED4 (see FIG. 21) described later.

For example, in the electronic device ED1, the semiconductor device PKG1 and the semiconductor device PKG2, which have different structures, are mounted on the mounting board MB1 so as to be adjacent to each other. However, for example, two or more semiconductor devices PKG1 may be mounted on the mounting board MB1 so as to be adjacent to each other.

For example, in the electronic device ED1, the metal plate MP1 of the semiconductor device PKG1 and the metal plate MP2 of the semiconductor device PKG2 are electrically connected through the heat sink HS. In a modification example, each of the metal plate MP1 of the semiconductor device PKG1 and the metal plate MP2 of the semiconductor device PKG2 may not be connected with the heat sink HS. In this case, an insulating adhesive is preferably arranged instead of the conductive member CM1 and the conductive member CM2 illustrated in FIG. 15. In this modification example, the insulating adhesive interposes between the metal plate MP1 of the semiconductor device PKG1 and the heat sink HS and between the metal plate MP2 of the semiconductor device PKG2 and the heat sink HS, and thus, the metal plate MP1 of the semiconductor device PKG1 and the metal plate MP2 of the semiconductor device PKG2 can be electrically isolated from each other.

As the insulating adhesive, a resin adhesive containing, for example, epoxy-based thermosetting resin can be exemplified. When the conductive member CM1 and the conductive member CM2 are replaced with the insulating adhesive, the heat dissipation property is reduced. Thus, inorganic particles (made of, for example, alumina or aluminum nitride) with electric insulation and higher heat conductivity than that of resin are particularly preferably mixed as a filler into the insulating resin.

### <Method of Manufacturing Electronic Device>

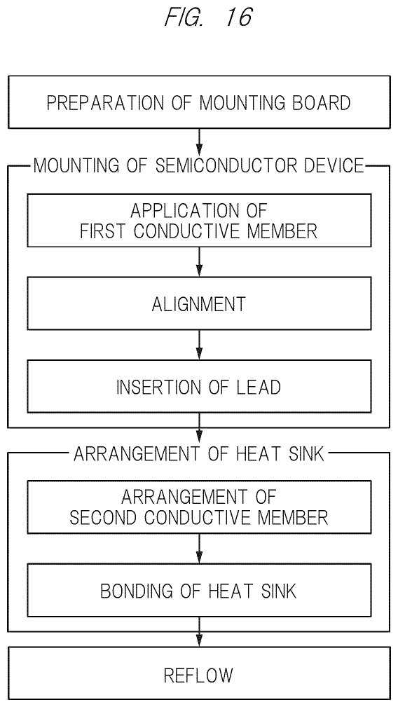

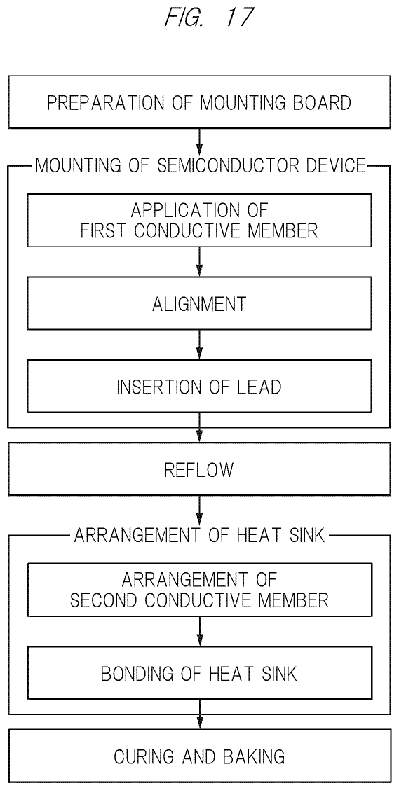

Next, a method of manufacturing the electronic device described with reference to FIGS. 13 to 15 will be described. FIG. 16 is an explanatory diagram illustrating exemplary steps of manufacturing the electronic device described with reference to FIGS. 13 to 15. FIG. 17 is an explanatory diagram illustrating a modification example of the manufacturing steps of FIG. 16. Note that the manufacturing steps of FIG. 16 correspond to an embodiment in which the solder is used for the conductive member CM1 and the conductive member CM2 of FIG. 15, and the manufacturing steps of FIG. 17 correspond to an embodiment in which the conductive resin is used for the conductive member CM1 and the conductive member CM2 of FIG. 15.

The method of manufacturing the electronic device illustrated in FIG. 16 includes a mounting-board preparing step, a semiconductor-device mounting step, a heat-sink arranging step, and a reflow step. The method of manufacturing the electronic device illustrated in FIG. 17 includes the mounting-board preparing step, the semiconductor-device mounting step, the reflow step, the heat-sink arranging step, and a curing and baking step.

### <Mounting Board Preparing Step>

At first, in the mounting-board preparing step of FIGS. 16 and 17, the mounting board MB1 illustrated in FIGS. 14 and 15 is prepared. The mounting board MB1 includes the mounting surface MBt, the insulating film SR1 (see FIG. 15) provided on the mounting surface MBt, the plurality of terminals TM exposed from the insulating film SR1 at the plurality of opening portions formed in the insulating film SR1, and the insulating layer IL1 (see FIG. 15) on which the plurality of terminals TM are formed.

In the present embodiment, the mounting board MB1 is previously provided with the plurality of holes HL1 formed in the insulating layer IL1. Each of the plurality of holes HL1 is formed to penetrate through the terminal TM in the thickness direction.

### <Semiconductor-Device Mounting Step>

Next, in the semiconductor-device mounting step of FIGS. 16 and 17, the semiconductor device PKG1 and the semiconductor device PKG2 are mounted on the mounting board MB1 so that the semiconductor device PKG1 and the semiconductor device PKG2 are adjacent to each other as illustrated in FIGS. 14 and 15. In the examples of FIGS. 16 and 17, the semiconductor-device mounting step includes a first-conductive-member applying step, an aligning step, and a lead inserting step.

In the first-conductive-member applying step, the solder SD (see FIG. 15) is applied to be in contact with each of the plurality of terminals TM. Strictly speaking, this solder SD is different from the solder SD of FIG. 15, and is paste solder containing a solder component and a flux component. Such a paste material is called solder paste. In the first-conductive-member applying step, the solder paste as a raw material of the solder SD is applied into each of the plurality of holes HL1.

Next, in the aligning step, for example, the semiconductor device PKG1 and the mounting board MB1 are first aligned. In the aligning step of the semiconductor device PKG1, the ends LDE of the outer lead sections LDX (see FIG. 4) of the plurality of leads LD1 in the semiconductor device PKG1 are aligned to position above the holes HL1. The step of aligning the semiconductor device PKG2 and the mounting board MB1 is performed after end of the lead inserting step of the semiconductor device PKG1. The aligning step of the semiconductor device PKG2 is similar to the aligning step of the semiconductor device PKG1, and thus, will not be repeatedly described.

Next, in the lead inserting step, for example, the plurality of leads LD1 of the semiconductor device PKG1 are first inserted into the holes HL1, respectively. As a result, the plurality of leads LD1 are in contact with the solder paste in the holes HL1.

In the lead inserting step, the distance between the semiconductor device PKG1 and the mounting board MB1 is reduced so that the lower surface MRb of the sealing body MR in the semiconductor device PKG1 is in contact with the mounting surface MBt of the mounting board MB1. Similarly, in the lead inserting step, the distance between the semiconductor device PKG2 and the mounting board MB1 is reduced so that the lower surface MRb of the sealing body MR in the semiconductor device PKG2 is in contact with the mounting surface MBt of the mounting board MB1. In other words, in this step, the semiconductor device PKG1 and the semiconductor device PKG2 are arranged so that the lower surfaces MRb (specifically, the entire lower surfaces MRb) of the semiconductor device PKG1 and the semiconductor device PKG2 are in contact with the mounting surface MBt of the mounting board MB1.

A stage of completion of this step is a stage before the curing of the solder paste by the reflow processing. Thus, a state of the semiconductor device PKG1 and the semiconductor device PKG2 is a state in which the semiconductor devices are bonded on the mounting board MB1 through the solder paste.

In the example of FIG. 16, the heat-sink arranging step is performed subsequent to the lead inserting step. To the contrary, in the example of FIG. 17, the reflow step is performed after the lead inserting step (in other words, after the semiconductor-device mounting step) and before the heat-sink arranging step. The description will be made in line with the example of FIG. 16.

In the heat-sink arranging step, after the semiconductor-device mounting step, the heat sink HS is arranged to straddle the semiconductor device PKG1 and the semiconductor device PKG2. The heat-sink arranging step includes a second-conductive-member arranging step and a heat-sink bonding step.

In the second-conductive-member arranging step, the conductive member CM1 illustrated in FIG. 15 is arranged on the exposed surface MP1b of the metal plate MP1 in the semiconductor device PKG1 while the conductive member CM2 is arranged on the exposed surface MP2t of the metal plate MP2 in the semiconductor device PKG2. In the example of FIG. 16, the conductive member CM1 and the conductive member CM2, for example, are solder. In this case, in this step, the solder paste is applied onto the exposed surface MP1b of the metal plate MP1 in the semiconductor device PKG1 and the exposed surface MP2t of the metal plate MP2 in the semiconductor device PKG2.

Next, in the heat-sink bonding step, the heat sink HS is arranged to straddle the semiconductor device PKG1 and the semiconductor device PKG2 as illustrated in FIGS. 14 and 15. The heat sink HS is bonded to the semiconductor device PKG1 and the semiconductor device PKG2 through the solder paste.

In the example of FIG. 16, the reflow step is performed after the heat-sink arranging step. In the reflow step, the ambient temperature of the solder SD, the conductive member CM1, and the conductive member CM2 is risen to the melting point of the solder as the raw material of the solder SD, the conductive member CM1, and the conductive member CM2 illustrated in FIG. 15, or higher. The flux component contained in the solder paste is infiltrated to periphery of the solder paste by the temperature rise, and activates the bonding interface of the solder. By the activation, an oxide film formed on the metal surface for bonding the solder is removed, and the solder is made wet. Thereafter, the solder is cured by cooling to provide the solder SD, the conductive member CM1, and the conductive member CM2 illustrated in FIG. 15. The organic components as the flux component or a binder material contained in the solder paste vaporize in the temperature rise of the reflow processing. If a residue remains, a cleaning processing needs to be performed after the reflow processing.

Since the solder contained in the solder paste is cured, the plurality of leads LD1 and the plurality of leads LD2 are fixed to the mounting board MB1. The heat sink HS is fixed to the metal plate MP1 of the semiconductor device PKG1 through the conductive member CM1, and is fixed to the metal plate MP2 of the semiconductor device PKG2 through the conductive member CM2. In other words, the example of FIG. 16 includes a step of fixing the heat sink HS to the metal plate MP1 and the metal plate MP2 through the conductive members (the conductive member CM1 and the conductive member CM2) after the heat-sink arranging step.

In the example of FIG. 16, the semiconductor device PKG1 and the semiconductor device PKG2 are fixed to the mounting board MB1 by the reflow processing. The heat sink HS is fixed to the semiconductor device PKG1 and the semiconductor device PKG2 by the reflow processing.

In the example of FIG. 16, the reflow processing is performed to the solder paste arranged in the plurality of holes HL1, the solder paste arranged on the semiconductor device PKG1, and the solder paste arranged on the semiconductor device PKG2, collectively (at the same time). Thus, the electric connection interface can be prevented from being contaminated due to gas generated from the organic materials during the heating processing.

To the contrary, in the example of FIG. 16, the reflow processing is performed while the heat sink HS is arranged, and thus, there is a problem that the temperature of the conductive member CM1 and the conductive member CM2 is difficult to rise. The modification example of FIG. 17 is more advantageous in this point than the example of FIG. 16.

The manufacturing method in a modification example will be described below with reference to FIG. 17. Note that the modification example of FIG. 17 is similar to the example of FIG. 16 from the beginning to the semiconductor-device mounting step. Thus, differences from the example of FIG. 16 will be mainly described below.

As described above, in the example of FIG. 17, the conductive member illustrated as the solder SD in FIG. 15 is made of solder, and the conductive member CM1 and the conductive member CM2 are made of conductive resin. In this case, the reflow step is performed after the semiconductor-device mounting step and before the heat-sink arranging step as illustrated in FIG. 17. As described above, in the reflow step, the solder paste arranged in the hole HL1 is heated to the melting point of the solder or higher, and is then cooled, thereby fixing the semiconductor device PKG1 and the semiconductor device PKG2 to the mounting board MB1.

In the second-conductive-member arranging step in the heat-sink arranging step of FIG. 17, the paste-like (in other words, thermally-uncured) conductive resin paste is applied on the exposed surface MP1b of the metal plate MP1 in the semiconductor device PKG1 and the exposed surface MP2t of the metal plate MP2 in the semiconductor device PKG2. The conducive resin paste is a raw material of the conductive member CM1 and the conductive member CM2 illustrated in FIG. 15. The conductive resin paste is a paste material containing the conductive particles made of, for example, silver and the resin containing thermosetting resin. In this step, a previously sheet-shaped conductive resin sheet may be used instead of the paste material.

Next, in the heat-sink bonding step, as illustrated in FIGS. 14 and 15, the heat sink HS is arranged to straddle the semiconductor device PKG1 and the semiconductor device PKG2. The heat sink HS is bonded to the semiconductor device PKG1 and the semiconductor device PKG2 through the conductive resin paste.

The example of FIG. 17 includes the curing and baking step of performing the curing and baking processing in order to cure the thermosetting resin contained in the conductive resin paste after the heat-sink arranging step. In the curing and baking step, the conductive resin paste is heated to the curing temperature of the thermosetting resin contained in the conductive resin paste or higher, thereby fixing the heat sink HS to the semiconductor device PKG1 and the semiconductor device PKG2.

In the curing and baking step, the thermosetting resin can be cured at a lower temperature than the solder SD. Therefore, the temperature can be risen to a needed temperature even if the heating is performed while the heat sink HS is attached. The modification example of FIG. 17 is more advantageous in this point than the example of FIG. 16.

To the contrary, in the example of FIG. 17, the semiconductor device PKG1 and the semiconductor device PKG2 are heated to a high temperature in the reflow step, and thus, the oxide film may be formed on the exposed surfaces (the exposed surface MP1b and the exposed surface MP2t) of the metal plate MP1 and the metal plate MP2 which are exposed from the sealing body, respectively. A film may be formed due to gas generated in the heating. The film may need to be removed depending on a thickness of the film. The method of manufacturing the electronic device illustrated in FIG. 16 is more advantageous in this point.

When the conductive member CM1 and the conductive member CM2 are replaced with the insulating adhesive as described above in the modification example, the insulating adhesive is arranged instead of the conductive member CM1 and the conductive member CM2 in the second-conductive-member arranging step in the flow of FIG. 17.

### First Modification Example of Electronic Device

Next, modification examples of the electronic device described with reference to FIGS. 13 to 15 will be described. FIG. 18 is an enlarged cross-sectional view of an electronic device as a modification example of FIG. 15. FIG. 19 is an enlarged cross-sectional view of an electronic device as a modification example of FIG. 18. Differences between the electronic device ED2 of FIG. 18 and the electronic device ED1 of FIG. 15 and differences between the electronic device ED2 of FIG. 18 and the electronic device ED3 of FIG. 19 will be described below.

The electronic device ED2 of FIG. 18 is different from the electronic device ED1 of FIG. 15 in the following points. That is, the metal plate MP1 of a semiconductor device PKG1A in the electronic device ED2 includes a screw hole SWH1 formed on the exposed surface MP1b. The metal plate MP2 of a semiconductor device PKG2A in the electronic device ED2 includes a screw hole SWH2 formed on the exposed surface MP2t. The heat sink HS of the electronic device ED2 is fixed to the semiconductor device PKG1A by a screw SW1 fastened in the screw hole SWH1, and is fixed to the semiconductor device PKG2A by a screw SW2 fastened in the screw hole SWH2 of the semiconductor device PKG2A.

The screw SW1 and the screw SW2 are made of metal. A helical groove is formed on a side surface of each of the screw hole SWH1 and the screw hole SWH2. The helical grooves of the screw SW1 and the screw SW2 are engaged with and fixed to the helical grooves of the screw hole SWH1 and the screw hole SWH2, respectively.

When the heat sink HS is fixed by the screw SW1 and the screw SW2 as described in the present modification example, high strength can be provided. In the example of FIG. 18, the exposed surface MP1b of the metal plate MP1 in the semiconductor device PKG1A is in contact with the lower surface HSb of the heat sink HS. The exposed surface MP2t of the metal plate MP2 in the semiconductor device PKG2A is in contact with the lower surface HSb of the heat sink HS. When the metal plate MP1 and the metal plate MP2 are in direct contact with the heat sink HS as described above, heat dissipation efficiency is improved.

However, in order to increase the contact area between the metal plate MP1 and the metal plate MP2 and the heat sink HS, the facing surfaces of them need to be flattened. If either or both of the lower surface HSb of the heat sink HS and the exposed surface MP1b of the metal plate MP1 (or the exposed surface MP2t of the metal plate MP2) are uneven in height, a gap is formed therebetween, and becomes a cause of a decrease in the heat dissipation property.

Thus, in the electronic device ED3 of FIG. 19 as another modification example, a heat dissipation sheet HDS is arranged between the semiconductor device PKG1A and the heat sink HS and between the semiconductor device PKG2A and the heat sink HS. The heat dissipation sheet (resin sheet) HDS of FIG. 19 is, for example, a resin sheet (sheet-shaped resin) in which inorganic particles (made of, for example, alumina, aluminum nitride, or metallic particles) with higher heat conductivity than that of resin are mixed as the filler into the resin.

In the present modification example, the heat sink HS is fixed by the screw SW1 and the screw SW2, and thus, adhesiveness of the heat dissipation sheet HDS is not required. In the present modification example, the screw SW1 is electrically connected with the metal plate MP1 while the screw SW2 is electrically connected with the metal plate MP2. Thus, conductivity of the heat dissipation sheet HDS is not required. Thus, the heat dissipation sheet HDS is adoptable because the gap is difficult to be formed between the heat sink HS and the metal plate MP1 (or the metal plate MP2) and because the heat dissipation property of the heat dissipation sheet HDS is high. Therefore, the degree of freedom in the adoption of the heat dissipation sheet HDS is high.

In the electronic device ED1 of FIG. 18 and the electronic device ED2 of FIG. 19, the metal plate MP1 of the semiconductor device PKG1A is electrically connected with the semiconductor chip CP1. Thus, the semiconductor chip CP1 is electrically connected with the heat sink HS through the metal plate MP1 and the screw (conductive member) SW1. The metal plate MP2 of the semiconductor device PKG2A is electrically connected with the semiconductor chip CP2. Thus, the semiconductor chip CP2 is electrically connected with the heat sink HS through the metal plate MP2 and the screw (conductive member) SW2.

In a modification example, however, if the semiconductor chip CP1 is not electrically connected with the metal plate MP1 of the semiconductor device PKG1A, the semiconductor chip CP1 is electrically isolated from the heat sink HS. Similarly, if the semiconductor chip CP2 is not electrically connected with the metal plate MP2 of the semiconductor device PKG2A, the semiconductor chip CP2 is electrically isolated from the heat sink HS.

The structures of the electronic device ED2 of FIG. 18 and the structure of the electronic device ED3 of FIG. 19 are similar to that of the electronic device ED1 of FIG. 15 except the above points. The semiconductor device PKG1A of FIGS. 18 and 19 is similar to the semiconductor device PKG1 of FIG. 15 except that the semiconductor device PKG1A includes the screw hole SWH1. The semiconductor device PKG2A of FIGS. 18 and 19 is similar to the semiconductor device PKG2 of FIG. 15 except that the semiconductor device PKG2A includes the screw hole SWH2. Therefore, the repetitive description thereof is omitted.

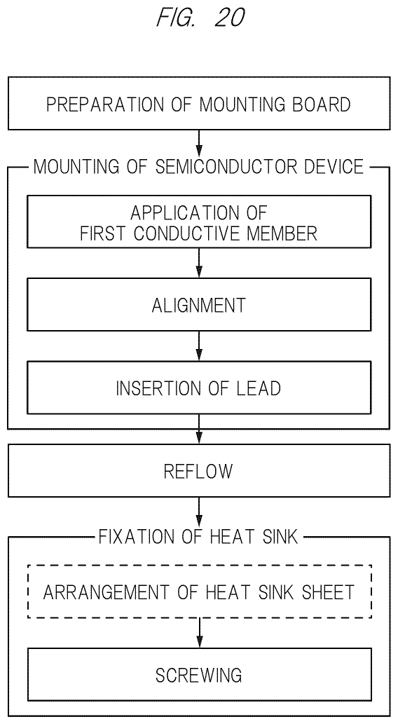

Next, a method of manufacturing the electronic device ED2 of FIG. 18 and the electronic device ED3 of FIG. 19 will be described. FIG. 20 is an explanatory diagram illustrating exemplary steps of manufacturing the electronic device of FIG. 18 or the electronic device of FIG. 19. The manufacturing steps of FIG. 20 are similar to the manufacturing steps of FIG. 17 from the beginning to the reflow step except that the screw hole SWH1 and the screw hole SWH2 illustrated in FIGS. 18 and 19 are previously formed in the semiconductor devices mounted in the semiconductor-device mounting step. Thus, differences from FIG. 17 will be described below.

The method of manufacturing the electronic device illustrated in FIG. 20 includes a heat-sink fixing step in addition to the mounting-board preparing step, the semiconductor-device mounting step, and the reflow step of FIG. 17. In the heat-sink fixing step, the heat sink HS is fixed to the metal plate MP1 and the metal plate MP2 as illustrated in FIGS. 18 and 19. Note that steps from the heat-sink arranging step to the reflow step in FIG. 16 and steps from the heat-sink arranging step to the curing and baking step in FIG. 17 can be regarded as the heat-sink fixing step in FIG. 20.

The heat-sink fixing step in the present modification example includes a screwing step. In the screwing step, as illustrated in FIG. 18, the heat sink HS is fixed to the semiconductor device PKG1A by the screw SW1 fastened in the screw hole SWH1, and is fixed to the semiconductor device PKG2A by the screw SW2 fastened in the screw hole SWH2 of the semiconductor device PKG2A.

In the method of manufacturing the electronic device ED3 of FIG. 19, the heat-sink fixing step includes a heat-dissipation-sheet arranging step before the screwing step. In the heat-dissipation-sheet arranging step, the heat dissipation sheet HDS of FIG. 19 is arranged on the metal plate MP1 of the semiconductor device PKG1A and the metal plate MP2 of the semiconductor device PKG2A. A through-hole into which the screw SW1 or the screw SW2 is inserted is previously formed in the heat dissipation sheet HDS. In the heat-dissipation-sheet arranging step, the through-hole formed in the heat dissipation sheet HDS is aligned to position on the screw hole SWH1 of the metal plate MP1 or the screw hole SWH2 of the metal plate MP2.

The method of manufacturing the electronic device in FIG. 20 is similar to the method of manufacturing the electronic device in FIG. 17 except for the above points. Thus, the repetitive description thereof is omitted.

### Second Modification Example of Electronic Device

Next, another modification example of the electronic device of FIGS. 13 to 15 will be described. The modification example of the electronic device ED1 of FIG. 15 will be typified and mainly described below. However, structures of a semiconductor device PKG1B and a semiconductor device PKG2B illustrated in FIG. 21 are similar to those of the semiconductor device PKG1 and the semiconductor device PKG2 illustrated in FIG. 15 except for the shape of the end of the outer lead section LDX. The following technique is applicable as a modification example of the semiconductor device PKG1A and the semiconductor device PKG2A described with reference to FIGS. 18 and 19. That is, the technique described in the present modification example is applicable while being combined with the technique described in the section “First Modification Example of Electronic Device>.

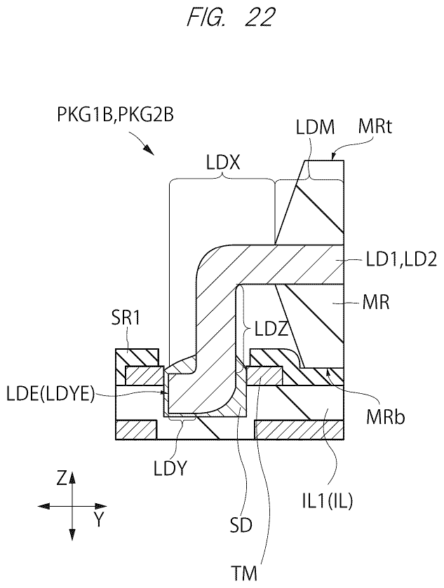

FIG. 21 is an enlarged cross-sectional view illustrating another modification example of FIG. 15. FIG. 22 is an enlarged cross-sectional view illustrating one of a plurality of leads of FIG. 21 to be enlarged. The electronic device ED4 of FIG. 21 is different from the electronic device ED1 of FIG. 15 in the shapes of the leads in the semiconductor device PKG1B and the semiconductor device PKG2B.

As illustrated in FIG. 22, the shape of the outer lead section LDX of the lead LD1 (or the lead LD2) in the semiconductor device PKG1B (or the semiconductor device PKG2B) in the present modification example is different from that in the semiconductor device PKG1 of FIG. 4 and the semiconductor device PKG2 of FIG. 12.

In the present modification example, as illustrated in FIG. 22, the outer lead section LDX further includes a section (portion) LDY which is coupled to the section LDZ extending from the upper surface MRt toward the lower surface MRb in the thickness direction (the Z direction) of the sealing body MR and extends to intersect the Z direction (in other words, extends in the Y direction). Thus, the end LDE of the outer lead section LDX is included in not the section LDZ but the section LDY. In other words, in the present modification example, the end LDE of the outer lead section LDX coincides with an end LDYE of the section LDY. In the present modification example, the section LDZ is coupled to the section LDY, and thus, there is no end of the section LDZ. That is, the end LDE of the outer lead section LDX does not coincide with the end LDZE of the section LDZ of FIG. 4. Therefore, the semiconductor device PKG1B and the semiconductor device PKG2B illustrated in FIG. 21 are classified into a semiconductor package closer to the SOP than the DIP.

As illustrated in FIG. 21, even in the semiconductor device PKG1B (or the semiconductor device PKG2B) including the section LDY (see FIG. 22), the lower surface MRb of the sealing body MR can be brought into contact with the mounting surface MBt of the mounting board MB1 by forming the hole HL1 in the mounting board MB1 and inserting the end of the lead LD1 (or the lead LD2) into the hole HL1.

In the present modification example, when the entire section LDY is housed in the hole HL1 (see FIG. 21) as illustrated in FIG. 22, the contact area between the solder SD and the lead LD1 (or the lead LD2) can be increased. Consequently, the mounting strength of the semiconductor device PKG1B and the semiconductor device PKG2B on the mounting board MB1 is higher than the mount strength of the semiconductor device PKG1 and the semiconductor device PKG2 on the mounting board MB1 in FIG. 15.

To the contrary, as can be seen from the comparison between FIG. 15 and FIG. 21, an opening diameter of the hole HL1 needs to be increased in order to house the entire section LDY (see FIG. 22) into the hole HL1. Thus, the electronic device ED1 of FIG. 15 is preferable in the viewpoint of the decrease of the opening area of the hole HL1 to decrease the mounting area.

As can be seen from the comparison between FIG. 15 and FIG. 21, the hole HL1 needs to be deep in order to house the entire section LDY (see FIG. 22) into the hole HL1. Thus, the electronic device ED1 of FIG. 15 is preferable in the viewpoint of making the hole HL1 shallow to prevent interference from the wiring layer WL of the mounting board MB1.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
a semiconductor chip;
a sealing body including a first surface and a second surface opposite the first surface and configured to seal the semiconductor chip;
a plurality of leads electrically connected with the semiconductor chip; and
a metal plate including a first exposed surface exposed from the sealing body at the first surface of the sealing body,
wherein each of the plurality of leads includes:
an inner lead portion sealed with the sealing body; and
an outer lead portion exposed from the sealing body,
wherein the outer lead portion includes a first portion extending from the first surface toward the second surface in a thickness direction of the sealing body,
wherein the first portion includes an end of the outer lead portion, and
wherein when it is assumed that the second surface is a first reference surface in side view, in the thickness direction of the sealing body, a distance from the end of the outer lead portion to the first reference surface is less than a distance from the first surface to the first reference surface.

2. The semiconductor device according to claim 1,
wherein the semiconductor chip includes a power transistor made of a power MOSFET or an IGBT, and
wherein the metal plate is electrically connected to a drain or a source of the power MOSFET or to a collector or an emitter of the IGBT.

3. The semiconductor device according to claim 1,
wherein the metal plate includes a screw hole formed at the first exposed surface.

4. An electronic device comprising:
a mounting board including a mounting surface;
a first semiconductor device mounted on the mounting surface of the mounting board;
a second semiconductor device mounted on the mounting surface of the mounting board so as to be adjacent to the first semiconductor device; and
a heat sink fixed onto each of the first semiconductor device and the second semiconductor device and straddling the first semiconductor device and the second semiconductor device,
wherein each of the first semiconductor device and the second semiconductor device includes:
a semiconductor chip;
a sealing body including: a first surface facing the heat sink, and a second surface opposite the first surface and configured to seal the semiconductor chip;
a plurality of leads electrically connected with the semiconductor chip; and
a metal plate including a first exposed surface exposed from the sealing body at the first surface of the sealing body,
wherein each of the plurality of leads includes:
an inner lead portion sealed with the sealing body; and
an outer lead portion exposed from the sealing body,
wherein the outer lead portion includes a first portion extending from the first surface toward the second surface in a thickness direction of the sealing body,
wherein when it is assumed that the second surface is a first reference surface in side view, in the thickness direction of the sealing body, a distance from an end of the outer lead portion to the first reference surface is less than a distance from the first surface to the first reference surface, and
wherein the second surface of each of the first semiconductor device and the second semiconductor device is in contact with the mounting surface of the mounting board.

5. The electronic device according to claim 4,
wherein the mounting board includes:
a first insulating film provided on the mounting surface;
a plurality of terminals exposed from the first insulating film at a plurality of opening portions formed in the first insulating film; and
a first insulating layer on which the plurality of terminals are formed,
wherein the first insulating film is formed on the first insulating layer,
wherein the plurality of terminals are formed around a plurality of holes formed in the insulating layer, respectively,
wherein the end of the outer lead portion is inserted into each of the plurality of holes, and
wherein the plurality of terminals and the plurality of leads are electrically connected through a first conductive member arranged in the plurality of holes.

6. The electronic device according to claim 5,
wherein the plurality of holes penetrate through the plurality of terminals but do not penetrate through the first insulating layer.

7. The electronic device according to claim 5,
wherein the metal plate of the first semiconductor device is a first metal plate while the metal plate of the second semiconductor device is a second metal plate, and
wherein the heat sink is fixed to the first metal plate and the second metal plate through a second conductive member.

8. The electronic device according to claim 7,
wherein the semiconductor chip of the first semiconductor device is a first semiconductor chip while the semiconductor chip of the second semiconductor device is a second semiconductor chip,
wherein the first semiconductor chip is electrically connected to the heat sink through the first metal plate and the second conductive member, and
wherein the second semiconductor chip is electrically connected to the heat sink through the second metal plate and the second conductive member.

9. The electronic device according to claim 8,
wherein each of the first conductive member and the second conductive member is made of solder.

10. The electronic device according to claim 8,
wherein the first conductive member is made of solder while the second conductive member is made of conductive resin.

11. The electronic device according to claim 8,
wherein each of the first semiconductor chip and the second semiconductor chip includes a power transistor made of a power MOSFET or an IGBT,
wherein the first metal plate is electrically connected to a source of the power MOSFET or an emitter of the IGBT in the first semiconductor chip, and
wherein the second metal plate is electrically connected to a drain of the power MOSFET or a collector of the IGBT in the second semiconductor chip.

12. The electronic device according to claim 6,
wherein the metal plate of the first semiconductor device is a first metal plate while the metal plate of the second semiconductor device is a second metal plate,
wherein the first metal plate includes a first screw hole formed in the first exposed surface,
wherein the second metal plate includes a second screw hole formed in the first exposed surface,
wherein the heat sink is fixed to the first semiconductor device by a first screw fastened in the first screw hole, and is fixed to the second semiconductor device by a second screw fastened in the second screw hole of the second semiconductor device.

13. The electronic device according to claim 12,
wherein the semiconductor chip of the first semiconductor device is a first semiconductor chip while the semiconductor chip of the second semiconductor device is a second semiconductor chip,
wherein the first semiconductor chip is electrically connected to the heat sink through the first metal plate and the first screw, and
wherein the second semiconductor chip is electrically connected to the heat sink through the second metal plate and the second screw.

14. A method of manufacturing an electronic device comprising steps of:
(a) preparing a mounting board including a mounting surface, a first insulating film provided on the mounting surface, a plurality of terminals exposed from the first insulating film at a plurality of opening portions formed in the first insulating film, and a first insulating layer on which the plurality of terminals is formed;
(b) mounting a first semiconductor device and a second semiconductor device on the mounting board such that the first semiconductor device and the second semiconductor device are adjacent to each other; and
(c) after the step (b), fixing a heat sink onto each of the first semiconductor device and the second semiconductor device so as to straddle the first semiconductor device and the second semiconductor device,
wherein each of the first semiconductor device and the second semiconductor device includes:
a semiconductor chip;
a sealing body including: a first surface facing the heat sink, and a second surface opposite the first surface and configured to seal the semiconductor chip;
a plurality of leads electrically connected with the semiconductor chip; and
a metal plate including a first exposed surface exposed from the sealing body at the first surface of the sealing body,
wherein each of the plurality of leads includes:
an inner lead portion sealed with the sealing body; and
an outer lead portion exposed from the sealing body,
wherein the outer lead portion includes a first portion extending from the first surface toward the second surface in a thickness direction of the sealing body,
wherein when it is assumed that the second surface is a first reference surface in side view, in the thickness direction of the sealing body, a distance from an end of the outer lead portion to the first reference surface is less than a distance from the first surface to the first reference surface, and
wherein in the step (b), the first semiconductor device and the second semiconductor device are arranged such that the second surface of each of the first semiconductor device and the second semiconductor device is in contact with the mounting surface of the mounting board.

15. The method of manufacturing the electronic device according to claim 14,
wherein the plurality of terminals are formed around a plurality of holes formed in the first insulating layer, respectively, and
wherein in the step (b), the end of the outer lead portion is inserted into each of the plurality of holes on which a first conductive member is applied.

16. The method of manufacturing the electronic device according to claim 15,
wherein the metal plate of the first semiconductor device is a first metal plate while the metal plate of the second semiconductor device is a second metal plate, and
the method further includes, after the step (c),
a step (d) of fixing the heat sink to each of the first metal plate and the second metal plate through a second conductive member.

17. The method of manufacturing the electronic device according to claim 16,
wherein each of the first conductive member and the second conductive member is made of solder,
wherein in the step (d), a reflow processing of heating each of the first conductive member and the second conductive member to a melting point of the solder or higher, and then, cooling the first conductive member and the second conductive member is performed,
wherein each of the first semiconductor device and the second semiconductor device is fixed to the mounting board by the reflow processing, and
wherein the heat sink is fixed to each of the first semiconductor device and the second semiconductor device by the reflow processing.

18. The method of manufacturing the electronic device according to claim 16,
wherein the first conductive member is made of solder while the second conductive member is made of conductive resin,
the method further includes, after the step (b) and before the step (c),
a step (e) of fixing each of the first semiconductor device and the second semiconductor device to the mounting board by heating the first conductive member to a melting point of the solder or higher, and then, cooling the first conductive member,
wherein in the step (d), the heat sink is fixed to each of the first semiconductor device and the second semiconductor device by heating to a curing temperature of thermosetting resin contained in the conductive resin or higher.

19. The method of manufacturing the electronic device according to claim 15,
wherein the metal plate of the first semiconductor device is a first metal plate while the metal plate of the second semiconductor device is a second metal plate,
wherein the first metal plate includes a first screw hole formed in the first exposed surface,
wherein the second metal plate includes a second screw hole formed in the first exposed surface,
the method further includes, after the step (c),
a step (d) of fixing the heat sink to each of the first metal plate and the second metal plate,
wherein in the step (d), the heat sink is fixed to the first semiconductor device by a first screw fastened in the first screw hole, and is fixed to the second semiconductor device by a second screw fastened in the second screw hole of the second semiconductor device.

20. The method of manufacturing the electronic device according to claim 19,
wherein the semiconductor chip of the first semiconductor device is a first semiconductor chip while the semiconductor chip of the second semiconductor device is a second semiconductor chip,
wherein the first semiconductor chip is electrically connected to the heat sink through the first metal plate and the first screw, and
wherein the second semiconductor chip is electrically connected to the heat sink through the second metal plate and the second screw.
